(19) United States
(12) Patent Application Publication
(10) Pub. No.: US 2020/0194581 A1
(43) Pub. Date: Jun. 18, 2020

(54) SEMICONDUCTOR DEVICE AND METHOD FOR FORMING THE SAME

(71) Applicant: Vanguard International Semiconductor Corporation, Hsinchu (TW)

(72) Inventors: Kai-Chuan KAN, Hsinchu City (TW); Shu-Wei HSU, Hsinchu City (TW); Chien-Hsien SONG, Kaohsiung City (TW); Tzu-Hsuan CHEN, Taipei City (TW)

(73) Assignee: Vanguard International Semiconductor Corporation, Hsinchu (TW)

(21) Appl. No.: 16/223,927

(22) Filed: Dec. 18, 2018

(51) Int. Cl. H01L 29/78; H01L 29/10; H01L 29/08; H01L 29/06; H01L 29/66; H01L 27/088

(52) U.S. Cl. CPC H01L 29/78; H01L 29/1083; H01L 27/088; H01L 29/0642; H01L 29/66477; H01L 29/0847

(57) ABSTRACT

A semiconductor device includes a semiconductor substrate, a buried layer disposed in the semiconductor substrate, and a first well region, a second well region, a third well region and a fourth well region disposed in the semiconductor substrate on the buried layer. The semiconductor device also includes a source region disposed in the second well region, a drain region disposed in the first well region, a gate structure disposed on the first well region and the second well region, and a deep trench isolation structure disposed in the semiconductor substrate and surrounding the source region and the drain region. The second well region surrounds the first well region. The third well region and the fourth well region are located on opposite sides of the second well region. The deep trench isolation structure penetrates through the buried layer.

### BACKGROUND

Embodiments of the present disclosure relate to a semiconductor device, and in particular they relate to a semiconductor device having a deep trench isolation structure and a method for forming the same.

Semiconductor devices have been widely used in various electronic products, such as personal computers, cellular phones, and digital cameras, for example. These semiconductor devices are usually fabricated by forming insulating layers or dielectric layers, conductive layers, and semiconductor layers on a semiconductor substrate, and then using a photolithography process to pattern the various formed material layers, thereby forming electrical circuit parts and components on the semiconductor substrate.

Although existing semiconductor devices and methods of fabricating the same may generally meet basic demands, with the continued demand for miniaturization of semiconductor devices, they are not satisfactory in every respect.

### SUMMARY

Some embodiments of the present disclosure relate to a semiconductor device. The semiconductor device includes a semiconductor substrate, a buried layer disposed in the semiconductor substrate, a first well region disposed in the semiconductor substrate on the buried layer, and a second well region disposed in the semiconductor substrate on the buried layer. The second well region surrounds the first well region. The semiconductor device also includes a third well region and a fourth well region disposed in the semiconductor substrate on the buried layer. The third well region and the fourth well region are located on opposite sides of the second well region. The semiconductor device also includes a source region disposed in the second well region, a drain region disposed in the first well region, a gate structure disposed on the first well region and the second well region, and a deep trench isolation structure disposed in the semiconductor substrate and surrounding the source region and the drain region. The deep trench isolation structure penetrates through the buried layer.

Some embodiments of the present disclosure further relate to a semiconductor device. The semiconductor device includes a semiconductor substrate, a buried layer disposed in the semiconductor substrate, a first well region disposed in the semiconductor substrate on the buried layer, and a second well region disposed in the semiconductor substrate on the buried layer. The second well region surrounds the first well region. The semiconductor device also includes a third well region and a fourth well region disposed in the semiconductor substrate on the buried layer. The third well region and the fourth well region are adjacent to the second well region, and the third well region and the fourth well region are separate from each other. The buried layer, the first well region, the third well region and the fourth well region have a first conductivity type, while the second well region has a second conductivity type that is the opposite of the first conductivity type. The semiconductor device also includes a source region disposed in the second well region, a drain region disposed in the first well region, a gate structure disposed on the first well region and the second well region, and a deep trench isolation structure disposed in the semiconductor substrate and surrounding the second well region. The bottom surface of the deep trench isolation structure is lower than the bottom surface of the buried layer.

Some embodiments of the present disclosure relate to a method for forming a semiconductor device. The method includes providing a semiconductor substrate. A buried layer is disposed in the semiconductor substrate. The method also includes forming a first well region, a second well region, a third well region and a fourth well region in the semiconductor substrate on the buried layer. The second well region surrounds the first well region. The third well region and the fourth well region partially surround the second well region, and the third well region and the fourth well region are separate from each other. The buried layer, the first well region, the third well region and the fourth well region have a first conductivity type, while the second well region has a second conductivity type that is the opposite of the first conductivity type. The method also includes forming a source region in the second well region, forming a drain region in the first well region, forming a gate structure on the first well region and the second well region, and forming a deep trench isolation structure in the semiconductor substrate.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial top view illustrating a semiconductor device according to an embodiment of the present disclosure.

FIG. 2 is a partial cross-sectional view along line A-A in FIG. 1 illustrating the semiconductor device according to an embodiment of the present disclosure.

FIG. 3 is a partial cross-sectional view along line B-B in FIG. 1 illustrating the semiconductor device according to an embodiment of the present disclosure.

FIG. 4 is a partial top view illustrating a plurality of semiconductor devices according to an embodiment of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meaning as commonly understood by one of ordinary skill in the art to which this invention belongs. It should be understood that terms, such as those defined in commonly used dictionaries, should be interpreted as having a meaning that is consistent with their meaning in the context of the relevant art and will not be interpreted in an idealized or overly formal sense unless expressly so defined in the embodiments of the present disclosure.

The semiconductor device, according to the embodiments of the present disclosure, includes a plurality of wells (e.g., the third well 106 and the fourth well 108 which will be described below) partially surrounding a source region, and includes a deep trench isolation structure surrounding the source region and a drain region. Therefore, the size of the semiconductor device may be reduced, the occurrence of leakage current in the substrate may be reduced or avoided, and the latch-up effect may be avoided or reduced.

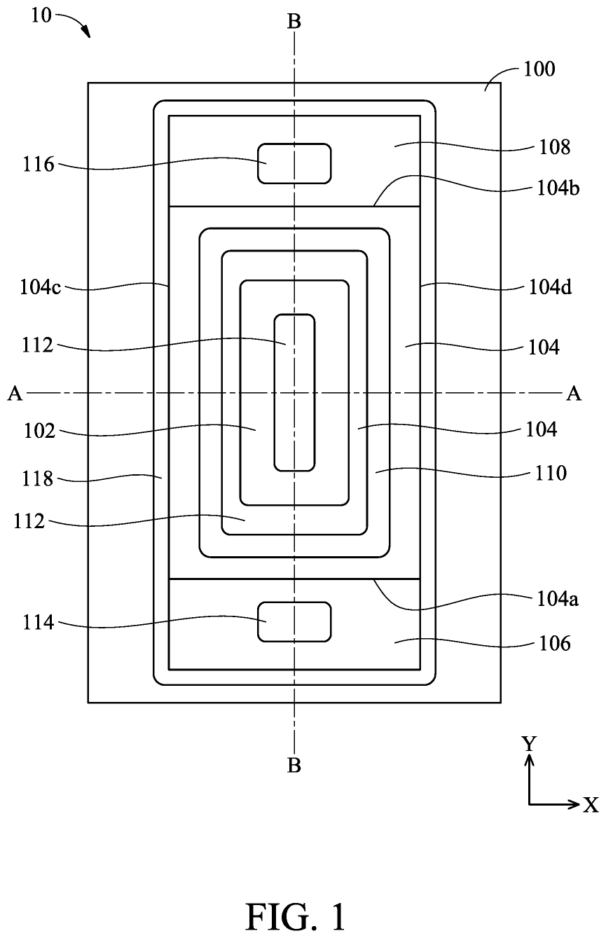

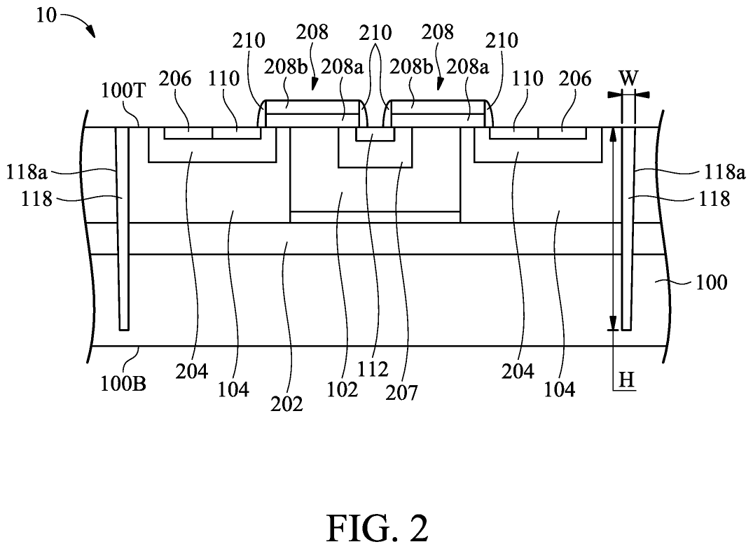

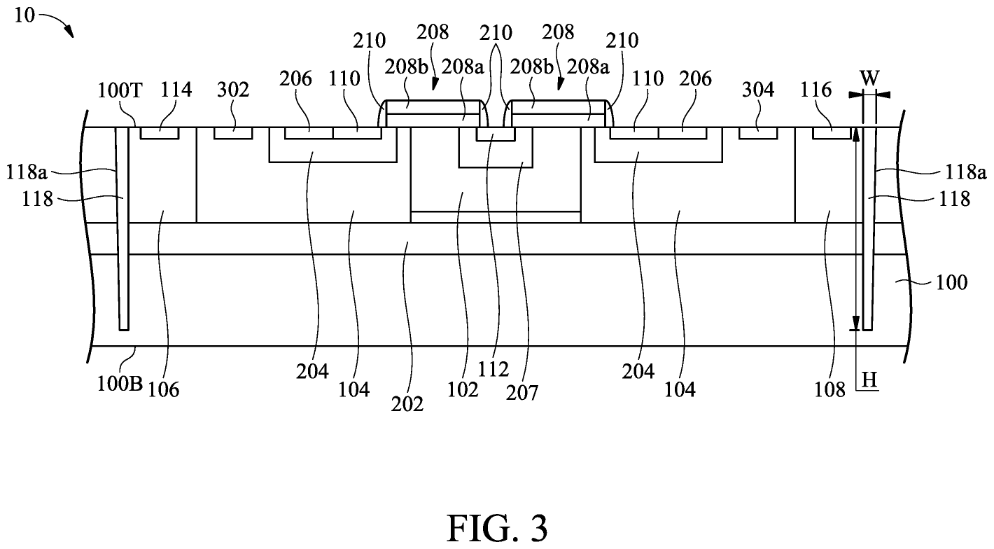

First, referring to FIGS. 1, 2 and 3, FIG. 1 is a partial top view illustrating a semiconductor device 10 according to some embodiments of the present disclosure, FIG. 2 is a partial cross-sectional view illustrating along line A-A in FIG. 1, and FIG. 3 is a partial cross-sectional view illustrating along line B-B in FIG. 1. In detail, line A-A is substantially parallel with the X direction, line B-B is substantially parallel with the Y direction, and the X direction is substantially perpendicular to the Y direction. It should be noted that not all components of the semiconductor device 10 are shown in FIGS. 1-3, for the sake of brevity.

As shown in FIGS. 1-3, the semiconductor device 10 includes at least one portion of a semiconductor substrate 100. The semiconductor substrate 100 may be a silicon substrate, but the present disclosure is not limited thereto. For example, the semiconductor substrate 100 may include some elemental semiconductor substrates (e.g., germanium). The semiconductor substrate 100 may also include compound semiconductor substrates (e.g., tantalum carbide, gallium arsenide, indium arsenide or indium phosphide). The semiconductor substrate 100 may also include alloy semiconductor substrates (e.g., silicon germanium, silicon germanium carbide, gallium arsenic phosphide or gallium indium phosphide). In some embodiments, the semiconductor substrate 100 may include semiconductor on insulator (SOI) substrates, such as silicon on insulator substrates or germanium on insulator substrates. The semiconductor on insulator substrate may include a base plate, a buried oxide layer disposed on the base plate and a semiconductor layer disposed on the buried oxide layer. In some embodiments, the semiconductor substrate 100 may include single crystal substrates, multi-layer substrates, gradient substrates, other suitable substrates or the combination thereof.

As shown in FIGS. 2, 3, the semiconductor substrate 100 may have a top surface 100T and a bottom surface 100B opposite to the top surface 100T. Appropriate doped regions and components may be formed between the top surface 100T and the bottom surface 100B for forming the semiconductor device 10, which will be described in detail below.

The semiconductor substrate 100 may have a second conductivity type. Hereinafter, an embodiment in which the second conductivity type of the semiconductor substrate 100 is P-type (i.e. the semiconductor substrate 100 is a P-type semiconductor substrate) will be described for the sake of brevity. However, in some other embodiments, the second conductivity type of the semiconductor substrate 100 may also be N-type.

As shown in FIGS. 2, 3, a buried layer 202 may be disposed in the semiconductor substrate 100. In some embodiments, an appropriate voltage may be applied to the buried layer 202 through a well region and a doped region that are disposed on the buried layer to avoid or reduce the latch-up effect, which will be described in detail below.

The buried layer 202 may have a first conductivity type that is the opposite of the second conductivity type. In some embodiments, the semiconductor substrate 100 is a P-type substrate, so the buried layer 202 is an N-type buried layer. In some embodiments, the N-type buried layer 202 may include dopants such as nitrogen, phosphorus, arsenic, antimony, or bismuth, the doping concentration of which may be between 10¹⁷ and 10¹⁸ cm⁻³. For example, appropriate dopants may be implanted into a portion of the semiconductor substrate 100 by an ion implantation process to form the buried layer 202.

Referring to FIGS. 1-3, according to some embodiments, a first well region 102 and a second well region 104 of the semiconductor device 10 may be formed in the semiconductor 100. In some embodiments, the second well region 104 surrounds the first well region 102 as shown in FIG. 1. In some embodiments, the first well region 102 and the second well region 104 are located on the buried layer 202 as shown in FIGS. 2, 3.

The first well region 102 may have the first conductivity type, while the second well region 104 may have the second conductivity type. In other words, the conductivity type of the first well region 102 is the opposite of the conductivity type of the second well region 104. In some embodiments, the first well region 102 is an N-type well region, while the second well region 104 is a P-type well region. In some embodiments, the N-type first well region 102 may include dopants such as nitrogen, phosphorus, arsenic, antimony, or bismuth, the doping concentration of which may be between 10¹⁶ and 10¹⁷ cm⁻³. In some embodiments, the P-type second well region 104 may include dopants such as boron, aluminum, gallium, indium, or thallium, the doping concentration of which may be between 10¹⁶ and 10¹⁷ cm⁻³. For example, appropriate dopants may be implanted into a portion of the semiconductor substrate 100 by an ion implantation process to form the first well region 102 and the second well region 104.

In some embodiments, the first well region 102 and the buried layer 202 are separate from each other as shown in FIGS. 2, 3, so that the source and the drain may be isolated to achieve the effect of complete isolation of components. In some embodiments, the second well region 104 is in direct contact with the buried layer 202.

Referring to FIGS. 1-3, according to some embodiments, a third well region 106 and a fourth well region 108 of the semiconductor device 10 may be formed in the semiconductor 100. In some embodiments, the third well region 106 and the fourth well region 108 are located on the buried layer 202 as shown in FIG. 3. In some embodiments, the third well region 106 and the fourth well region 108 are adjacent to the second well region 104, and the third well region 106 and the fourth well region 108 are separated from each other by the second well region 104 as shown in FIGS. 1, 3.

In some embodiments, as shown in FIG. 1, the third well region 106 and the fourth well region 108 just partially surround the second well region 104. In other words, they do not completely surround the second well region 104, so that the size of the semiconductor device 10 may be reduced. In some embodiments, as shown in FIGS. 1, 3, the third well region 106 is located on a first side 104a of the second well region 104, while the fourth well region 108 is located on a second side 104b, which is opposite to the first side 104a of the second well region 104. In some embodiments, the first side 104a of the second well region 104 is in direct contact with the third well region 106, and the second side 104b of the second well region 104 is in direct contact with the fourth well region 108.

The third well region 106 and the fourth well region 108 may have the first conductivity type. In other words, the conductivity type of the third well region 106 and the fourth well region 108 is the same as the conductivity type of the buried layer 202. In some embodiments, the buried layer 202 is an N-type buried layer, so the third well region 106 and the fourth well region 108 are N-type well regions. In some embodiments, the N-type third well region 106 includes dopants such as nitrogen, phosphorus, arsenic, antimony, or bismuth, the doping concentration of which may be between 10¹⁶ and 10¹⁷ cm⁻³. In some embodiments, the N-type fourth well region 108 includes dopants such as nitrogen, phosphorus, arsenic, antimony, or bismuth, the doping concentration of which may be between 10¹⁶ and 10¹⁷ cm⁻³. The doping concentration of the third well region 106 may substantially be equal to the doping concentration of fourth well region 108. However, the embodiments of the present disclosure are not limited thereto. For example, appropriate dopants may be implanted into a portion of the semiconductor substrate 100 by an ion implantation process to form the third well region 106 and the fourth well region 108.

Referring to FIGS. 2, 3, according to some embodiments, the semiconductor device 10 may include a doped region 204 formed in the second well region 104. In some embodiments, the doped region 204 may surround the first well region 102. In some embodiments, the doped region 204 is separated from the first well region 102 by the second well region 104 as shown in FIGS. 2, 3.

The doped region 204 may have the second conductivity type. In other words, the doped region 204 may have the same conductivity type as the second well region 104. In some embodiments, the second well region 104 is a P-type well region, so the doped region 204 is a P-type doped region. In some embodiments, the P-type doped region 204 may include dopants such as boron, aluminum, gallium, indium, or thallium, the doping concentration of which may be between 10¹⁷ and 10¹⁸ cm⁻³. In some embodiments, the doping concentration of the doped region 204 is higher than the doping concentration of the second well region 104. For example, appropriate dopants may be implanted into a portion of the semiconductor substrate 100 by an ion implantation process to form the doped region 204 in the second well region 104.

Referring to FIGS. 1-3, according to some embodiments, a source region 110 of the semiconductor device 10 is formed in the second well region 104, and a drain region 112 is formed in the first well region 102. In some embodiments, the source region 110 of the semiconductor device 10 is formed in the doped region 204 in the second well region 104. In some embodiments, the source region 110 surrounds the drain region 112 as shown in FIG. 1.

The source region 110 and the drain region 112 may have the first conductivity type. In other words, the conductivity type of the source region 110 and the drain region 112 may be the opposite of the conductivity type of the second well region 104. In some embodiments, the second well region 104 is a P-type well region, so the source region 110 and the drain region 112 are an N-type source region and an N-type drain region. In some embodiments, the N-type source region 110 includes dopants such as nitrogen, phosphorus, arsenic, antimony, or bismuth, the doping concentration of which may be between 10¹⁸ and 10¹⁹ cm⁻³. In some embodiments, the N-type drain region 112 includes dopants such as nitrogen, phosphorus, arsenic, antimony, or bismuth, the doping concentration of which may be between 10¹⁸ and 10¹⁹ cm⁻³. For example, appropriate dopants may be implanted into a portion of the semiconductor substrate 100 by an ion implantation process to form the source region 110 and the drain region 112.

Referring to FIGS. 2, 3, according to some embodiments, the semiconductor device 10 may include a doped region 206 formed in the doped region 204. In some embodiments, the doped region 206 surrounds the source region 110. In some embodiments, the conductivity type of the doped region 206 is the opposite of the conductivity type of the source region 110, and the doped region 206 is in direct contact with the source region 110, so that the characteristic resistance value of the component may be reduced.

In some embodiments, the source region 110 is an N-type source region, so the doped region 206 is a P-type doped region. In some embodiments, the P-type doped region 206 may include dopants such as boron, aluminum, gallium, indium, or thallium, the doping concentration of which may be between 10¹⁸ and 10¹⁹ cm⁻³. In some embodiments, the doping concentration of the doped region 206 is higher than the doping concentration of the doped region 204. For example, appropriate dopants may be implanted into a portion of the semiconductor substrate 100 by an ion implantation process to form the doped region 206 in the doped region 204.

Referring to FIG. 3, according to some embodiments, the semiconductor device 10 may include a doped region 302 and a doped region 304 formed in the second well region 104. In some embodiments, the doped region 302 and the doped region 304 are separate from the doped region 204. In some embodiments, the doped region 302 and the doped region 304 surround the doped region 204. The conductivity type of the doped region 302 and the doped region 304 may be the same as the conductivity type of the second well region 104. In some embodiments, the second well region 104 is a P-type well region, so the doped region 302 and the doped region 304 are P-type doped regions. In some embodiments, the P-type doped region 302 may include dopants such as boron, aluminum, gallium, indium, or thallium, the doping concentration of which may be between 10¹⁸ and 10¹⁹ cm⁻³. In some embodiments, the P-type doped region 304 may include dopants such as boron, aluminum, gallium, indium, or thallium, the doping concentration of which may be between 10¹⁸ and 10¹⁹ cm⁻³. For example, appropriate dopants may be implanted into a portion of the semiconductor substrate 100 by an ion implantation process to form the doped region 302 and the doped region 304.

Referring to FIGS. 2, 3, according to some embodiments, the semiconductor device 10 may include a doped region 207 formed in the first well region 102. In some embodiments, the doped region 207 is in direct contact with a side wall and a bottom surface of the drain region 112. In some embodiments, the doped region 207 may optimize the ability of the electrostatic discharge (ESD) of the component.

The conductivity type of the doped region 207 may be the same as the conductivity type of the drain region 112. In some embodiments, the drain region 112 is an N-type drain region, so the doped region 207 is an N-type doped region. In some embodiments, the N-type doped region 207 includes dopants such as nitrogen, phosphorus, arsenic, antimony, or bismuth, the doping concentration of which may be between 10¹⁶ and 10¹⁷ cm⁻³. In some embodiments, the doping concentration of the doped region 207 is lower than the doping concentration of the drain region 112. For example, appropriate dopants may be implanted into a portion of the semiconductor substrate 100 by an ion implantation process to form the doped region 207 in the first well region 102.

Referring to FIGS. 1, 3, according to some embodiments, the semiconductor device 10 may include a doped region 114 formed in the third well region 106 and a doped region 116 formed in the fourth well region 108. In some embodiments, an appropriate voltage may be applied to the buried layer 202 through the doped region 114, the third well region 106, the doped region 116 and the fourth well region 108 to avoid or reduce the latch-up effect.

In some embodiments, the conductivity type of the doped region 114 and the doped region 116 is the same as the conductivity type of the third well region 106 and the fourth well region 108 (i.e. the doped region 114, the doped region 116, the third well region 106 and the fourth well region 108 all have the first conductivity type). In some embodiments, the third well region 106 and the fourth well region 108 are N-type well regions, so the doped region 114 and the doped region 116 are N-type doped regions. In some embodiments, the N-type doped region 114 includes dopants such as nitrogen, phosphorus, arsenic, antimony, or bismuth, the doping concentration of which may be between 10¹⁸ and 10¹⁹ cm⁻³. In some embodiments, the N-type doped region 116 includes dopants such as nitrogen, phosphorus, arsenic, antimony, or bismuth, the doping concentration of which may be between 10¹⁸ and 10¹⁹ cm⁻³. In some embodiments, the doping concentration of the doped region 114 and the doped region 116 is higher than the doping concentration of the third well region 106 and the fourth well region 108. For example, appropriate dopants may be implanted into a portion of the semiconductor substrate 100 by an ion implantation process to form the doped region 114 and the doped region 116.

Referring to FIGS. 1-3, according to some embodiments, the semiconductor device 10 may include a deep trench isolation structure 118 formed in the semiconductor substrate 100. In some embodiments, the deep trench isolation structure 118 extends from the top surface 100T of the semiconductor substrate 100 into the semiconductor substrate 100. In some embodiments, the deep trench isolation structure 118 extends through the buried layer 202. In some embodiments, the bottom surface of the deep trench isolation structure 118 is lower than the bottom surface of the buried layer 202 and higher than the bottom surface 100B of the semiconductor substrate 100. In some embodiments, the deep trench isolation structure 118 extends through the buried layer 202 and enters the semiconductor substrate 100 under the buried layer 202, such that leakage current in the substrate may be avoided or reduced.

In some embodiments, the deep trench isolation structure 118 surrounds the second well region 104 as shown in FIG. 1. In some embodiments, the deep trench isolation structure 118 surrounds the third well region 106 and the fourth well region 108 as shown in FIG. 1. In some embodiments, since the deep trench isolation structure 118 surrounds the first well region 102, the second well region 104, the third well region 106, the fourth well region 108, and the doped regions (e.g., the source region 110, the drain region 112) formed in these well regions, leakage current in the substrate may be further avoided or reduced.

In some embodiments, the deep trench isolation structure 118 is in direct contact with the second well region 104, the third well region 106 and the fourth well region 108. In some embodiments, the deep trench isolation structure 118 is in direct contact with a third side 104c and a fourth side 104d opposite to the third side 104c of the second well region 104, as shown in FIG. 1. In some embodiments, the deep trench isolation structure 118 is in direct contact with the third side 104c and the fourth side 104d of the second well region 104 but separate from the first side 104a and the second side 104b of the second well region 104. In some embodiments, the deep trench isolation structure 118 is separated from the first side 104a of the second well region 104 by the third well region 106, and the deep trench isolation structure 118 is separated from the second side 104b of the second well region 104 by the fourth well region 108.

In some embodiments, a suitable etching process may be performed to form a trench 118a in the semiconductor substrate 100, and then the trench 118a may be filled with suitable insulating materials (e.g., silicon oxide, silicon nitride or silicon oxynitride) to form the deep trench isolation structure 118. In some embodiments, the etching process is an anisotropic etching process (e.g., a plasma etching process), such that the trench 118a may have a larger aspect ratio (i.e. H/W). For example, the aspect ratio of the trench 118a may be between 10 and 20. In some embodiments, a suitable planarization process (e.g., chemical-mechanical polishing process) may be performed to remove the insulating material outside the trench 118a, such that a top surface of the deep trench isolation structure 118 is substantially coplanar with the top surface 100T of the semiconductor substrate 100.

Referring to FIGS. 2, 3, according to some embodiments, the semiconductor device 10 includes a gate structure 208 formed on the first well region 102 and the second well region 104. In some embodiments, the gate structure 208 may surround the drain region 112. The gate structure 208 may include a gate dielectric layer 208a and a gate electrode layer 208b located on the gate dielectric layer 208a.

For example, the gate dielectric layer 208a may be formed of silicon oxide, silicon nitride, silicon oxynitride, high-κ dielectric material, any other suitable dielectric materials or a combination thereof. For example, the high-κ dielectric material may be LaO, AlO, ZrO, TiO, Ta₂O₅, Y₂O₃, SrTiO₃ (STO), BaTiO₃ (BTO), BaZrO, HfO₂, HfO₃, HfZrO, HfLaO, HfSiO, HfSiON, LaSiO, AlSiO, HfTaO, HfSiO, HfTaTiO, HfAlON, (Ba, Sr)TiO₃ (BST), Al₂O₃, other suitable high-κ dielectric materials or a combination thereof. In some embodiments, the gate dielectric layer 208a may be formed by a chemical vapor deposition, an atomic layer deposition or other suitable methods. For example, the chemical vapor deposition may be a low pressure chemical vapor deposition, a low temperature chemical vapor deposition, a rapid thermal chemical vapor deposition or a plasma-enhanced chemical vapor deposition.

For example, the gate electrode layer 208b may be formed of polycrystalline silicon, metal, metal alloy, metal nitride, metal silicide, metal oxide, other suitable conductive materials or a combination thereof. For example, the gate electrode layer 208b may be formed by a chemical vapor deposition process, a physical vapor deposition process (e.g., a vacuum evaporation process or sputtering process), other suitable processes or a combination thereof.

In some embodiments, the semiconductor device 10 may include a gate sidewall spacer 210 formed on the sidewall of the gate structure 208. For example, the gate sidewall spacer 210 may be formed of insulating materials, such as SiO₂, SiN, SiON, SiOCN or SiCN. For example, a blanket layer of an insulating material may be formed by the chemical vapor deposition process or other suitable processes, and then an anisotropic etching may be performed on the blanket layer of the insulating material to form the gate sidewall spacer 210 on the sidewall of the gate structure 208.

In summary, the semiconductor device 10 according to the embodiments of the present disclosure includes a third well region 106 located on the first side 104a of the second well region 104, a fourth well region 108 located on the second side 104b of the second well region 104, and a deep trench isolation structure 118 surrounding the first well region 102, the second well region 104, the third well region 106 and the fourth well region 108. Thereby the size of the semiconductor device 10 may be reduced, the occurrence of leakage current in the substrate may be reduced or avoided, and the latch-up effect may be avoided or reduced.

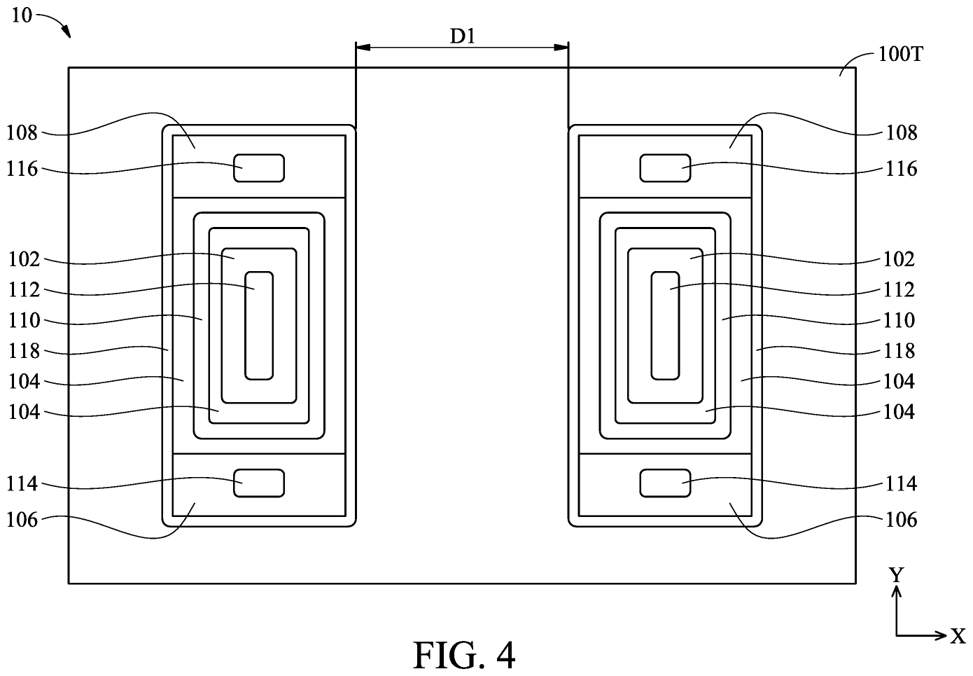

In some embodiments, a plurality of the semiconductor devices 10 may be disposed in and/or on the semiconductor substrate 100 as shown in FIG. 4. Since the second well regions 104 of these semiconductor devices 10 are only partially surrounded by the third well regions 106 and the fourth well regions 108, these semiconductor devices 10 have a smaller size in the X-direction and the integration density may be increased. In some embodiments, as shown in FIG. 4, the distance D1 between the two adjacent semiconductor devices 10 may be 3 to 4 micrometers.

In summary, the semiconductor device of the embodiments of the present disclosure includes a deep trench isolation structure surrounding the source region and the drain region, and thus the occurrence of leakage current in the substrate may be reduced or avoided. Furthermore, in the semiconductor device of the embodiments of the present disclosure, the drain region is formed in the first well region, the source region is formed in the second well region, and the third well region and the fourth well region that are electrically connected to the buried layer only partially surround the second well region, and thus the size of the semiconductor device may be reduced and the latch-up effect may be avoided or reduced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined by the claims. In addition, although some embodiments of the present disclosure are disclosed above, they are not intended to limit the scope of the present disclosure. Furthermore, not all advantages of the embodiments of the present disclosure are discussed.

1. A semiconductor device, comprising:
a semiconductor substrate;
a buried layer disposed in the semiconductor substrate;
a first well region disposed in the semiconductor substrate on the buried layer and separate from the buried layer;
a second well region disposed in the semiconductor substrate on the buried layer, wherein the second well region surrounds the first well region;
a third well region and a fourth well region disposed in the semiconductor substrate on the buried layer, wherein the third well region and the fourth well region are located on opposite sides of the second well region;
a source region disposed in the second well region;
a drain region disposed in the first well region;
a gate structure disposed on the first well region and the second well region; and
a deep trench isolation structure disposed in the semiconductor substrate and surrounding the source region and the drain region, wherein the deep trench isolation structure penetrates through the buried layer.

2. The semiconductor device of claim 1, wherein the third well region and the fourth well region are in direct contact with the buried layer.

3. The semiconductor device of claim 1, wherein the buried layer, the first well region, the third well region and the fourth well region have a first conductivity type, while the second well region has a second conductivity type that is the opposite of the first conductivity type.

4. The semiconductor device of claim 3, wherein the first conductivity type is N-type and the second conductivity type is P-type.

5. The semiconductor device of claim 3, further comprising:
a doped region disposed in the third well region,
wherein the doped region has the first conductivity type.

6. The semiconductor device of claim 1, wherein the deep trench isolation structure is in direct contact with the second well region, the third well region and the fourth well region.

7. A semiconductor device, comprising:
a semiconductor substrate;
a buried layer disposed in the semiconductor substrate;
a first well region disposed in the semiconductor substrate on the buried layer and separate from the buried layer;
a second well region disposed in the semiconductor substrate on the buried layer, wherein the second well region surrounds the first well region;
a third well region and a fourth well region disposed in the semiconductor substrate on the buried layer, wherein the third well region and the fourth well region are adjacent to the second well region, the third well region and the fourth well region are separate from each other, and the buried layer, the first well region, the third well region and the fourth well region have a first conductivity type, while the second well region has a second conductivity type that is the opposite of the first conductivity type;
a source region disposed in the second well region;
a drain region disposed in the first well region;
a gate structure disposed on the first well region and the second well region; and
a deep trench isolation structure disposed in the semiconductor substrate and surrounding the second well region, wherein a bottom surface of the deep trench isolation structure is lower than a bottom surface of the buried layer.

8. The semiconductor device of claim 7, further comprising:
a first doped region disposed in the second well region and having the second conductivity type, wherein the source region is disposed in the first doped region; and
a second doped region disposed in the first doped region and having the second conductivity type.

9. The semiconductor device of claim 8, wherein the source region is in direct contact with the second doped region.

10. The semiconductor device of claim 7, wherein the first conductivity type is N-type and the second conductivity type is P-type.

11. The semiconductor device of claim 7, wherein the deep trench isolation structure is in direct contact with the second well region, the third well region and the fourth well region.

12. The semiconductor device of claim 7, wherein the third well region and the fourth well region are in direct contact with the buried layer.

13. A method for forming a semiconductor device, comprising:
providing a semiconductor substrate, wherein a buried layer is disposed in the semiconductor substrate;
forming a first well region, a second well region, a third well region and a fourth well region in the semiconductor substrate on the buried layer, wherein the second well region surrounds the first well region, the third well region and the fourth well region partially surround the second well region, the third well region and the fourth well region are separate from each other, and the first well region is separate from the buried layer, and wherein the buried layer, the first well region, the third well region and the fourth well region have a first conductivity type, while the second well region has a second conductivity type that is the opposite of the first conductivity type;
forming a source region in the second well region;
forming a drain region in the first well region;
forming a gate structure on the first well region and the second well region; and
forming a deep trench isolation structure in the semiconductor substrate.

14. The method for forming the semiconductor device of claim 13, wherein the step of forming the deep trench isolation structure in the semiconductor substrate comprises:
etching the semiconductor substrate to form a trench in the semiconductor substrate; and
filling the trench with an insulating material.

15. The method for forming the semiconductor device of claim 14, wherein the trench penetrates the buried layer and surrounds the second well region.

16. The method for forming the semiconductor device of claim 13, wherein the first conductivity type is N-type and the second conductivity type is P-type.

17. The method for forming the semiconductor device of claim 13, further comprising:
forming a first doped region in the second well region, wherein the first doped region has the second conductivity type; and
forming a second doped region in the first doped region, wherein the second doped region has the second conductivity type and is in direct contact with the source region.

18. The method for forming the semiconductor device of claim 13, further comprising:
forming a doped region in the third well region, wherein the doped region has the first conductivity type.

19. The method for forming the semiconductor device of claim 13, wherein the deep trench isolation structure is in direct contact with the second well region, the third well region and the fourth well region.

20. The method for forming the semiconductor device of claim 13, wherein the third well region and the fourth well region are in direct contact with the buried layer.
